(19) United States
(12) Patent Application Publication
(10) Pub. No.: US 2025/0379438 A1
(43) Pub. Date: Dec. 11, 2025

(54) Cooled busbar and charging system

(71) Applicant: NEXANS, Courbevoie (FR)

(72) Inventor: Tobias KROOP, COURBEVOIE (FR)

(21) Appl. No.: 19/228,111

(22) Filed: Jun. 4, 2025

(30) Foreign Application Priority Data
Jun. 5, 2024 (DE) 102024115734.8

(51) Int. Cl. H02G 5/10; H02J 7/00; H05K 7/20

(52) U.S. Cl. CPC H02G 5/10; H02J 7/0042; H05K 7/20927

(57) ABSTRACT

An electric busbar (100) is provided, which is formed as a hollow profile (101), through the cavity (104) of which a coolant flows. The busbar has an inlet connection and an outlet connection, where the inlet connection is formed in such a way as to permit a coolant to flow into the cavity. The outlet connection is formed in such a way as to permit the coolant to flow out of the cavity. Contact pieces (107) are connected integrally and electrically conductively to the ends (106) of the busbar or the hollow profile and close the cavity tightly. A charging system is provided having such a busbar.

### RELATED APPLICATION

This application claims the benefit of priority from German Patent Application No. 102024115734.8, filed on Jun. 5, 2024, the entirety of which is incorporated by reference.

### FIELD

The invention relates to a cooled busbar and to a charging system having such a busbar, in particular for battery electric vehicles.

### BACKGROUND

The wide spread of electric vehicles is increasing continuously, which is desired politically and commercially in order to reduce exhaust gas pollution, in particular in metropolitan areas, and at the same time to reduce the emission of CO2 by traffic to the extent to which so-called green power is available for the operation of vehicles. One stumbling block to the further wide spread of electric vehicles, in addition to the limited electrical range, is the time period which is needed to charge the battery storage device (for short: battery) of a vehicle. Charging a battery of an electric vehicle still needs considerably more time than filling a conventional vehicle with an internal combustion engine, which can typically be accomplished in a few minutes. There is therefore the desire to shorten the necessary charging time by increasing the electrical charging current. Currently the charging voltages are up to 500 V in order to achieve a charging power of 50 KW. With such high charging currents, resistive heat also naturally develops in the conductors which connect the charging socket of the electric vehicle to its battery storage device. Nevertheless, in a fast charging operation which, for example, lasts for 15 minutes, limiting temperatures in particular on the connecting contacts of the charging socket and of the battery storage device must not be exceeded. One possible way of achieving this target is to enlarge the line cross section of the connecting line which connects the charging socket to the battery storage device and which is frequently designed as a busbar such that the permissible limiting temperatures are not reached at the critical points. The disadvantage with this approach is that a great deal of material usage is needed for this purpose and, at the same time, the vehicle weight increases, which is generally undesired. One alternative possibility is cooling the busbars which transport the charging current, in order to prevent limiting temperatures being reached or exceeded.

Starting from this point, the present invention has the object of devising a busbar and a charging system having such a busbar in order to overcome or at least to improve one or more of the problems mentioned at the beginning.

### DESCRIPTION OF THE INVENTION

To achieve this object, according to a first aspect the invention proposes an electric busbar which is formed as a hollow profile, through the cavity of which a coolant flows. The busbar has an inlet connection and an outlet connection, wherein the inlet connection is formed in such a way as to permit a coolant to flow into the cavity. The outlet connection is formed in such a way as to permit the coolant to flow out of the cavity. Contact pieces are connected integrally and electrically conductively to the ends of the busbar or the hollow profile and close the cavity tightly.

The busbar is primarily suitable for installation in electric vehicles to connect a charging socket to an electric battery storage device. Using the coolant which flows through the busbar, in particular during a fast charging operation, the temperature rise, above all on the contact pieces, is limited to values which are still permissible for contact points, for example to 90° C. The coolant also cools the contact piece by means of the integral connection between the busbar and the contact piece. At the same time, the contact pieces effect sealing of the cavity of the busbar and prevent the coolant from flowing out. The coolant thus moves through the busbar in a closed cooling circuit.

In a development of the busbar, the cavity is divided by partitions into a plurality of individual cavities.

In this exemplary embodiment, the contact surface between the coolant and the current-carrying metal is enlarged by means of the partitions. In this way, the cooling action of the coolant on the busbar is increased.

Advantageously, the coolant flows into a first individual cavity in a first flow direction. In a second individual cavity, the coolant flows in a second flow direction which is opposite to the first flow direction.

Using this embodiment of the busbar, a uniform temperature distribution can be achieved in charging systems which have two busbars.

According to a second aspect, the invention relates to a charging system for a battery electric power storage device. The charging system has a connection that can be connected to a power source, a current sink, a busbar according to the first aspect of the invention, which connects the power source to the current sink electrically, and a heat sink through which the coolant flows.

In one exemplary embodiment, the power source is a charging column and the current sink is a battery storage device. The charging column is connected by a charging cable to the usable connection and supplies the charging current for charging the battery storage device.

Advantageously, the charging system comprises two busbars, which are connected to each other at a respective end fluidically and insulated electrically from each other, so that the coolant flows out of one busbar and flows into the other busbar. The other ends of the two busbars have an inlet connection and an outlet connection, which are fluidically connected to the heat sink.

The heat sink can be any arrangement which is suitable to absorb heat from the coolant which flows through the busbars.

In one exemplary embodiment, the heat sink is a heat exchanger, a battery storage device, an electric machine and/or a device for controlling the temperature of an internal space.

In one embodiment, the heat exchanger is air-cooled.

Advantageously, the charging system can comprise two busbars, which each have two or more individual cavities, in which the coolant flows in opposite directions.

By means of this design of the charging system, both coolant which has cooled down in the heat sink and also coolant which has already flowed through the respective other busbar and has a higher temperature as compared with the coolant coming from the heat sink flows in each of the two busbars. This achieves the situation in which the two busbars have approximately the same temperature. By contrast, in a charging system in which the coolant has first flowed through one busbar and then the other busbar before it returns to the heat sink again, it is possible for temperature differences to occur between the busbars, which can result in a permissible limiting temperature being reached more quickly by the warmer busbar than in a charging system in which the busbars are at a uniform temperature.

### BRIEF DESCRIPTION OF THE DRAWING

The invention will be explained in more detail by way of example below using one embodiment with reference to the accompanying figures. All the figures are purely schematic and not to scale. In the figures:

FIG. 1A shows a busbar according to the invention;

FIG. 1B shows an alternative hose connection for a coolant for the busbar shown in FIG. 1A;

FIG. 1C shows a second alternative hose connection for a coolant for the busbar shown in FIG. 1A;

FIG. 2A-C show exemplary embodiments of a charging system having a busbar according to the invention; and

FIG. 3 shows a further busbar according to the invention in cross section.

The same or similar elements are provided with the same or similar reference signs in the figures.

### EXEMPLARY EMBODIMENT

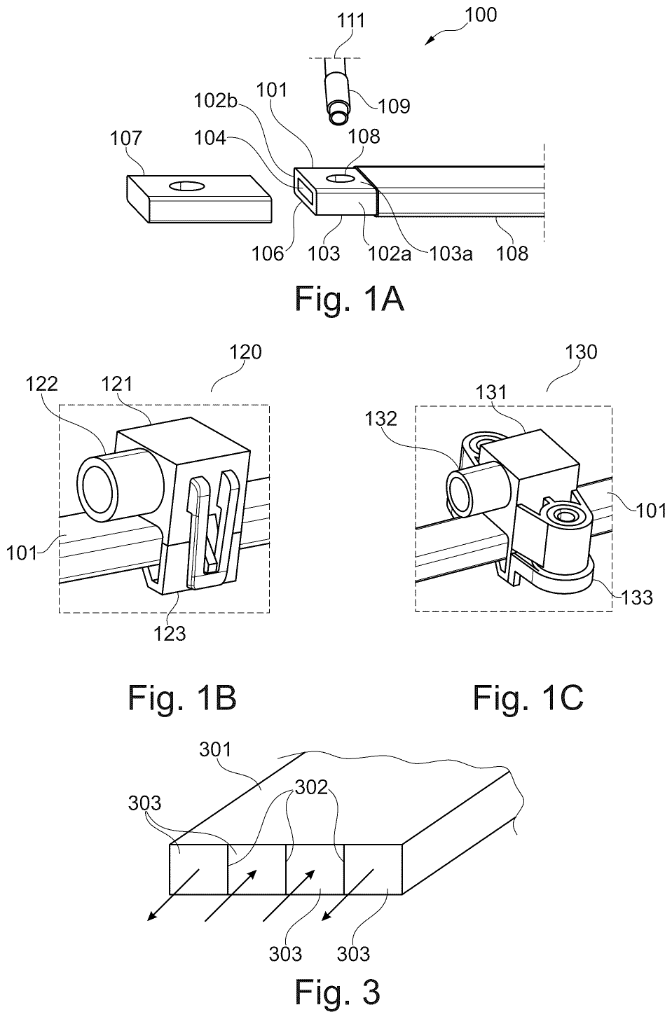

FIG. 1A shows a busbar 100 according to the present invention. The busbar 100 is formed from a rectangular tube 101, which has two narrow sides 102a,b and two wide sides 103a,b. In one exemplary embodiment of the busbar 100, the rectangular tube 101 is produced from aluminium or copper. In principle, the rectangular tube 101 can also consist of other electrically highly conductive materials. It is noted that the present invention is not restricted to rectangular tubes, instead other tube cross sections can also be used, for example round, oval or polygonal tube cross sections. However, the further description is based on rectangular tubes, since these are frequently used in practice. The narrow sides 102a,b and the wide sides 103a,b form a circumferential wall which encloses a cavity 104. The rectangular tube 101 has two ends 106, to each of which a contact piece 107 is attached by means of an integral connection, so that a mechanically stable connection is produced between the rectangular tube 101 and the contact pieces 107 and, at the same time, the internal space 104 is closed tightly at the ends 106 of the rectangular tube 101. The contact pieces 107 are, for example, welded on or brazed on. Provided in the wide side 103a is a threaded hole 108, into which a hose nipple 109 can be screwed in order to produce a fluidic connection between the internal space 104 and a hose 111. The threaded hole 108 illustrated in FIG. 1A forms an inlet opening. The end of the rectangular tube 101 that is not shown in FIG. 1A forms a corresponding outlet opening, which, with the arrangement comprising a further hose nipple and a hose 111, likewise produces a fluidic connection to the internal space 104 of the rectangular tube 101.

The rectangular tube 101 which is closed by contact pieces 107 at its ends 106 and is provided with an inlet and outlet opening forms a busbar 100 according to the present invention. The rectangular tube 101 fulfils two functions during the operation of the busbar 100, namely the function of an electric conductor by means of the walls of the rectangular tube 101, and the function of a fluid conductor for a coolant, wherein the cavity 104 enclosed by the walls of the rectangular tube 101 forms the fluid conductor. For electrical insulation, the rectangular tube 101 is enclosed by an insulating jacket 108.

Any free-flowing gaseous or liquid medium which has a low electrical, but a high thermal conductivity is suitable as coolant. In practice, liquids can be managed more easily than gases, for which reason, for brevity, the exemplary embodiments are described with a liquid as coolant, wherein this is not to be understood such that the invention is restricted to liquids as coolant. One example of a suitable cooling liquid can be obtained commercially from 3M under the trademark Novec 7000.

By means of the hoses 111, it is possible to lead a coolant through the busbar 100 in a circuit and, as a result, to control the temperature of the busbar. The contact pieces 107 are likewise cooled by thermal conduction between the rectangular tube 101 and the contact pieces 107. The cooling of the busbar 100 is effected by the fact that there is a transmission of heat from the rectangular tube and the walls of the rectangular tube to the coolant. The coolant in turn is cooled in a cooler. Any heat sink which lowers the 30 temperature of the coolant as it flows through functions as a cooler. Different configurations of a heat sink will be described further below.

FIG. 1B shows an alternative hose connection 120, which is constructed from two parts. One connecting component 121 has a hose fitting 122 which is fluidically connected to a connector (not illustrated in FIG. 1B) arranged on the connecting component 121 and produces a fluidic connection to the cavity 104 of the rectangular tube 101. The connecting component 121 is latched to a holding component 123, so that the rectangular tube 101 is led through between the connecting component 121 and the holding component 123. The hose fitting 122 is used to produce a cooling circuit for the coolant flowing in the rectangular tube 101 by a hose being pushed onto the hose fitting 122.

FIG. 1C shows a further alternative hose connection 130, which is constructed from two parts. One connecting component 131 has a hose fitting 132, which is fluidically connected to a connector (not illustrated in FIG. 1B) arranged on the connecting component and produces a fluidic connection to the cavity 104 of the rectangular tube 101. The connecting component 131 is screwed to a holding component 133 in such a way that the rectangular tube 101 is led through between the connecting component 131 and the holding component 133 and is clamped in. The hose fitting 132 can be used to produce a cooling circuit for the coolant flowing in the rectangular tube 101 with a hose. For this purpose, a hose is pushed onto the hose fitting 132.

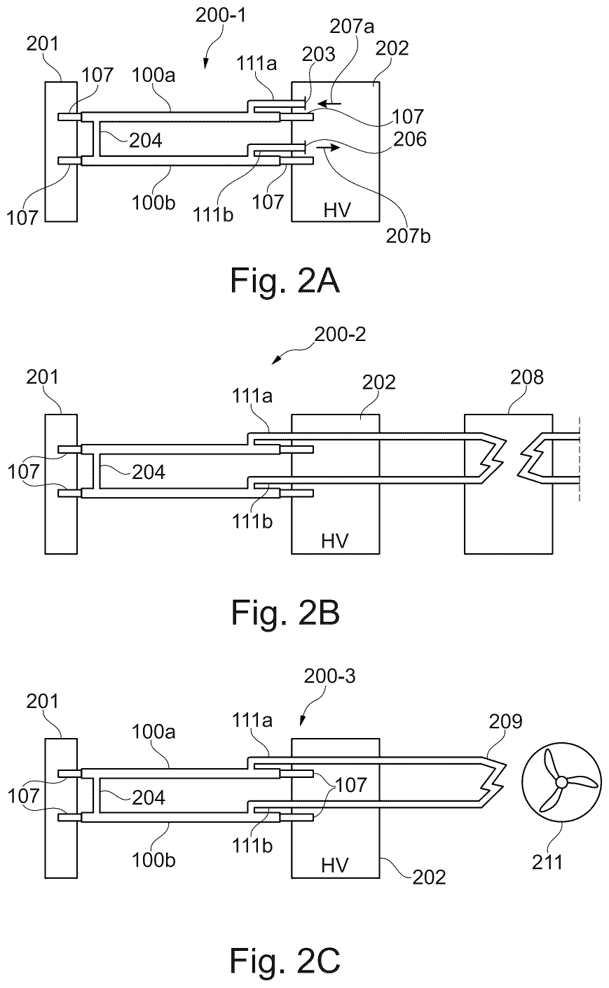

FIG. 2A schematically shows a detail of a charging system 200-1 for an electric vehicle, in particular a battery electric vehicle, in which, during a fast charging operation, very high charging currents flow which lead to correspondingly high heating in the current-carrying lines. An electric vehicle is one example of an application of the invention. In principle, the invention is suitable for all applications where high currents flow which lead to heating of the current-carrying conductors or contacts, which must not exceed permissible limiting temperatures and therefore make appropriate cooling of current-carrying lines and contacts necessary.

The charging system 200-1 comprises a charging socket 201 which is accessibly arranged on an outer side of a body of the electric vehicle. Plugged into the charging socket during a charging operation is a charging cable, which connects the charging socket to a charging column which supplies the current in order to charge a battery of the electric vehicle. The charging socket 201 is connected by two busbars 100a,b to a high voltage battery 202. For this purpose, the busbars 100a,b are connected, for example screwed on, by contact pieces 107 to corresponding connecting contacts on the charging socket 201 and the high voltage battery 202.

A hose 111a of the busbar 100a is connected to a coolant outlet 203 of the high voltage battery 202, which is equipped with a coolant circuit and has a dedicated coolant cooler (not illustrated). The coolant flows in the busbar 100a to a connecting piece 204 which is arranged at the opposite end of the busbar 100a and which connects a coolant outlet opening of the busbar 100a to a coolant inlet opening 206 of the busbar 100b. The coolant flows through the busbar 100b toward a hose 111b, which is connected to a coolant inlet 206 of the high voltage battery 202. The flow direction of the coolant is indicated by arrows 207a, 207b. The coolant cooled down by the cooling circuit of the high voltage battery 202 ensures cooling of the busbars 100a,b during a fast charging operation, which is time-limited or is aborted if a limiting temperature on a critical component of the charging system is exceeded.

FIG. 2B is a further schematic illustration of a charging system 200-2. By contrast to the charging system 200-1, the hoses 111 are not connected to a cooling circuit of the high voltage battery 202 but to a heat exchanger 208, which cools the coolant flowing into the busbars 100a,b and in this way dissipates heat from the busbars 100a,b. The heat exchanger 208 can be a dedicated heat exchanger, which is provided exclusively for the cooling of the coolant that flows in the busbar 100a,b. However, the heat exchanger 208 can also have a plurality of media circuits and, for example amongst other things, be used for the temperature control of a vehicle interior, of the high voltage battery and/or of a drive motor.

FIG. 2C schematically shows a further charging system 200-3, in which the coolant flowing in the busbars 100a,b flows through a cooling loop 209 and is cooled by an air stream which is generated by a fan 211.

In all the charging systems 200-1, 200-2 and 200-3, the cooling of the busbars 100a,b is dimensioned such that a fast charging operation can be carried out without interruption.

FIG. 3 shows a perspective view of a rectangular tube 301 for a busbar. The rectangular tube 301 has partitions 302, which divide an internal space enclosed by the rectangular tube 301 into a plurality of individual cavities 303. Coolant flows in the individual cavities in order to cool the rectangular tube 301. As a result of the partitions 302, the contact surface between the coolant and the current-carrying material of the rectangular tube is larger as compared with a rectangular tube having a single internal space.

Preferably, in a practical application in an electric vehicle, cooled coolant will flow from the heat sink into the busbar at a positive potential (HV+) and be guided back to the heat sink in the other busbar at ground potential (HV−). In principle, the coolant can also be guided in the opposite direction. However, the invention is not restricted to a specific flow direction. If busbars with rectangular tubes are used, opposite flow directions can also be present simultaneously, as is explained below.

In the individual cavities 303, the coolant can also flow in different directions so that, in a charging system having two busbars, both coolant which has cooled down in the heat sink and also coolant which has already flowed through the respective other busbar and has a higher temperature than the coolant coming from the heat sink flow through both busbars. In FIG. 3, the different flow directions are indicated by arrows 304. In this way, the situation is reached in which the two busbars have approximately the same temperature. By contrast, in a charging system in which the coolant flows first through one busbar and then through the other busbar before it returns to the heat sink again, it is possible for temperature differences to occur between the busbars, which can result in a permissible limiting temperature being reached more quickly by the warmer busbar than in a charging system in which the busbars are at a uniform temperature.

In principle, a user can define the flow direction as desired. In a practical embodiment, however, it has proven to be expedient if the coolant originating from the heat sink flows into the inner individual cavities 303, while the coolant inrushing from the respective other busbar flows in the outer individual cavities 303.

### LIST OF REFERENCE SIGNS

100 Busbar
101 Rectangular tube
102a,b Narrow side
103a,b Wide side
104 Cavity
106 Ends
107 Contact piece
108 Threaded hole
109 Hose nipple
111 Hose
200 Charging system
201 Charging sockets
202 High voltage battery
203 Coolant outlet
204 Connecting piece
206 Coolant inlet
207a,b Arrows
208 Heat exchanger
209 Cooling loop
211 Fan
301 Rectangular tube
302 Partition
303 Individual cavity
304 Arrow

1. An electric busbar, which is formed as a hollow profile, through the cavity of which a coolant flows, where the electric busbar comprises:
has an inlet connection and an outlet connection,
wherein the inlet connection is formed in such a way as to permit a coolant to flow into the cavity,
wherein the outlet connection is formed in such a way as to permit the coolant to flow out of the cavity,
wherein contact pieces are connected integrally and electrically conductively to the ends of the busbar or the hollow profile and close the cavity tightly.

2. The electric busbar according to claim 1, wherein the cavity is divided by partitions into a plurality of individual cavities.

3. The electric busbar according to claim 2, wherein the coolant flows in a first individual cavity in a first flow direction, and in that the coolant flows in a second individual cavity in a second flow direction, which is opposite to the first flow direction.

4. A charging system for a battery electric power storage device, wherein the charging system comprises:
a connection that can be connected to a power source,
a current sink,
a busbar according to claim 1, which connects the power source to the current sink electrically, and
a heat sink, through which the coolant flows.

5. The charging system according to claim 4, wherein the charging system further comprises two busbars which are connected to each other at a respective end by means of a connecting piece fluidically and insulated electrically from each other, so that the coolant flows out of one busbar and flows into the other busbar, wherein the other ends of the two busbars have an inlet connection and an outlet connection, which are fluidically connected to the heat sink.

6. The charging system according to claim 4, wherein the heat sink is a heat exchanger, a battery storage device, an electric machine and/or a device for controlling the temperature in an internal space.

7. The charging system according to claim 6, wherein the heat exchanger is air-cooled.

8. The charging system according to one of claim 5, wherein the two busbars each have two or more individual cavities, in which the coolant flows in opposite directions.
